(19) United States
(12) Patent Application Publication
(10) Pub. No.: US 2026/0279470 A1
(43) Pub. Date: Sep. 17, 2026

(54) Memory Circuit with Replica Column Multiplexer

(71) Applicant: TEXAS INSTRUMENTS INCORPORATED, Dallas, TX (US)

(72) Inventor: Lail Hajj-Ahmad, Richardson, TX (US)

(21) Appl. No.: 19/254,589

(22) Filed: Jun. 30, 2025

Related U.S. Application Data
(60) Provisional application No. 63/770,432, filed on Mar. 12, 2025.

(51) Int. Cl. G11C 16/34; G11C 16/04; G11C 16/24; G11C 16/30

(52) U.S. Cl. CPC G11C 16/3413; G11C 16/0483; G11C 16/24; G11C 16/30

(57) ABSTRACT

A system includes a memory circuit, which includes a bit cell array, a column multiplexer, and a current mirror circuit. The current mirror circuit includes compensating circuits to increase or reduce a bit cell programming current to achieve a desired value for the bit cell programming current, despite leakage current and bit cell process variation. The compensating circuits may include a replica column multiplexer and a splitting circuit.

### CROSS-REFERENCE TO RELATED APPLICATIONS

The present application claims the benefit of United States Provisional Patent Application 63/770,432, filed March 12, 2025, the disclosure of which is hereby incorporated by reference in its entirety.

### TECHNICAL FIELD

The present application relates to circuits, generally, and more specifically to memory circuits having replica column multiplexers.

### BACKGROUND

A non-volatile-memory bit cell may include an electronic element that is configured to store information. A bit line to source line current can be used to discriminate between logic levels of the bit cell, such as a logic low level (“0”) or a logic high level (“1”). This stored value may sometimes be referred to as information (or a bit). In some implementations, a memory circuit may program a bit cell by sinking current through a source line associated with the bit cell.

### SUMMARY

In an example embodiment, a circuit includes: a first column multiplexer; a common bitline coupled to the first column multiplexer; a current mirror circuit coupled to the common bitline, wherein the current mirror circuit has: a first leg having: a current source; and a diode coupled between the current source and a power supply terminal; a second leg having a first transistor that has a control terminal coupled to a control terminal of the diode, wherein a current path terminal of the first transistor is coupled to the first column multiplexer; and a second column multiplexer coupled to the diode.

In another example embodiment, a circuit includes: a column multiplexer; a common bitline coupled to the column multiplexer; a current mirror circuit coupled to the common bitline, wherein the current mirror circuit has: a first leg having: a first current source; and a diode coupled between the first current source and a power supply terminal; and a second leg having a first transistor that has a control terminal coupled to a control terminal of the diode, wherein a current path terminal of the first transistor is coupled to the column multiplexer; and a second current source; a second transistor having first and second current path terminals and a control terminal; and a third transistor having first and second current path terminals and a control terminal, wherein the first current path terminal of the second transistor is coupled to the second current source, the second current path terminal of the second transistor is coupled to the power supply terminal, and the control terminal of the second transistor is coupled to the second current path terminal of the third transistor, further wherein the first current path terminal of the third transistor is coupled to the second current source and the control terminal of the third transistor is coupled to the diode.

In another example embodiment, a circuit includes: an array of bit cells, the array of bit cells having a plurality of columns; a column multiplexer, wherein each of the columns is coupled to the column multiplexer, wherein the column multiplexer has N pairs of transmission gates, each pair of transmission gates being coupled to a respective column and to a common bitline, wherein N is an integer greater than one; a current mirror circuit having a first leg and a second leg, wherein the second leg of the current mirror circuit is coupled to the common bitline; M pairs of transmission gates coupled to the first leg of the current mirror circuit, wherein M is an integer greater than one; a first transistor having first and second current path terminals and a control terminal; and a second transistor having first and second current path terminals and a control terminal, wherein the first current path terminal of the first transistor and the first current path terminal of the second transistor are coupled to a first current source, wherein the second current path terminal of the first transistor is coupled to a power supply terminal, wherein the second current path terminal of the second transistor is coupled to the common bitline, and wherein the control terminal of the second transistor is coupled to the first leg of the current mirror circuit.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an illustration of an example memory circuit, according to some embodiments;

FIG. 2 is an illustration of an example program operation for the memory circuit of FIG. 1, according to some embodiments; and

FIG. 3 is an illustration of an example column multiplexer and an example current mirror circuit, according to the example program operation described with respect to FIG. 2; and

FIG. 4 is an illustration of the example column multiplexer and the example current mirror circuit, where the current mirror circuit includes an example replica column multiplexer and an example splitter circuit, according to the example program operation described with respect to FIGS. 2-3.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

The present disclosure is described with reference to the attached figures. The figures are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

The description below illustrates various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Various memory circuits, such as flash memory circuits, may use a column multiplexer to allow for multiple bit line columns to share a single sensing amplifier for read operations. Such column multiplexers may perform a second role during program operations. For instance, column multiplexers may steer a programming current through a single selected bit line column to a global bit line. A given column multiplexer may be associated with a current mirror. For instance, the current mirror may be arranged at the common bit line and may be configured to cause a desired programming current level.

During an example program operation, the programming current may traverse a current path from a select line, through a bit cell, through the column multiplexer to the common bit line and the current mirror. The column multiplexer may include a multitude of transmission gates, where a pair of transmission gates associated with the selected column may allow the programming current to pass and the remaining pairs of transmission gates associated with the unselected columns may be put in an off state. However, the unselected pairs of transmission gates may leak current into the programming path, effectively diverting programming current away from the bit to be programmed.

As complementary metal oxide semiconductor (CMOS) technology nodes shrink to smaller gate lengths, the cumulative leakage current from the unselected transmission gate pairs may become comparable in magnitude to the intended programming current. Furthermore, at high temperatures, when the cumulative multiplexer leakage encroaches (or even surpasses) the programming current, the selected bit cell may fail to program. Failure to program may be undesirable.

Various embodiments provide compensating circuits to the current mirror of a memory circuit to address the cumulative leakage current from the transmission gate pairs. One example embodiment may include a replica column multiplexer, coupled to the gate of the current mirror. For instance, the current mirror may have a first leg (e.g., a diode leg) and a second leg. Some example embodiments may arrange the replica column multiplexer to leak current to the first leg. The leakage current from the replica column multiplexer may cause further current to be drawn through the common bit line, thereby allowing for greater programming current to flow through the selected bit cell.

A further compensating circuit may compensate for process variation of bit cells. For instance, some embodiments may add a current splitter that compares the voltage of the common bit line to a voltage appearing at the diode of the first leg. In this example, a diode may be implemented in any appropriate manner. For instance, a diode may be implemented as a two-terminal component or may be implemented using another component having more terminals (e.g., a transistor having gate and drain shorted). If the voltage at the common bit line is greater than the voltage at the diode, a current source equal to half the allowable programming current variation may be added to the second leg of the mirror, thereby ensuring that enough current traverses the selected bit cell for programming. If the common bit line voltage is less than the diode voltage, then the current splitter may divert some current to ground to avoid over-programming.

Various embodiments may include one or more potential advantages. For instance, various embodiments may allow for more reliable programming of bit cells by avoiding under-programming and over-programming. Under-programming may result in a failure to read and a susceptibility to flip states, and over-programming may result in damage to the bit cell. Various embodiments may reduce or eliminate under-programming and over-programming.

Furthermore, various embodiments may be implemented without substantially increasing a size of a memory circuit. For instance, the compensating circuits described herein may be implemented using N type metal oxide semiconductor (NMOS) transistors and P type metal oxide semiconductor (PMOS) transistors, which may not increase a size of the memory circuit to an undesirable degree. However, the scope of implementations is not limited to NMOS and PMOS transistors, as any appropriate transistor technology may be used, such as bipolar junction transistors (BJTs) and/or the like.

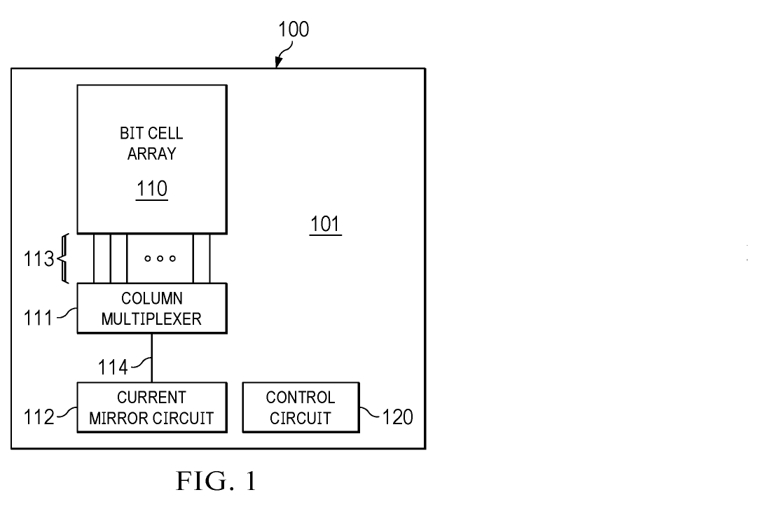

FIG. 1 is an illustration of an example memory circuit 100, according to some embodiments. Memory circuit 100 may be implemented as an integrated circuit (IC). For instance, the memory circuit 100 may be implemented on semiconductor chip 101. Furthermore, the semiconductor chip 101 may include only the memory circuit 100 or may include further components (e.g., processor cores, other memory circuits) as appropriate.

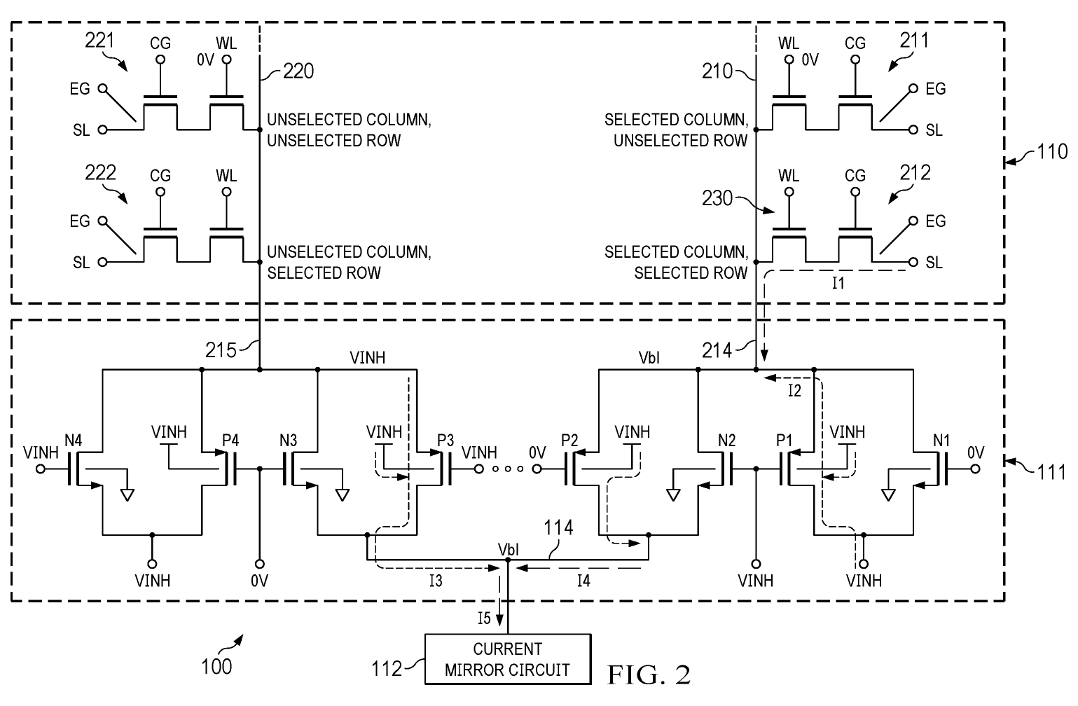

Memory circuit 100 includes bit cell array 110. For instance, the bit cell array 110 may include multiple columns 113, such as 16 columns, though the scope of implementations may include any appropriate quantity of columns in the bit cell array 110. As described in more detail with respect to FIG. 2, each column may be coupled to a multitude of different bit cells and select lines, which allow a particular bit cell of a particular column to be programmed while allowing the other bit cells of the same column as well as the bit cells of the unselected columns to be unchanged.

Column multiplexer 111 is coupled to the columns 113 and to a global bit line 114. During a programming operation for a bit cell, column multiplexer 111 may be controlled to select a single column at a time for programming by allowing current to traverse a current path from a bit in a selected column to the global bit line 114.

The global bit line 114 is coupled to the current mirror circuit 112. The current mirror circuit 112 may be configured to mirror a target programming current to cause that target programming current to traverse the current path from the selected bit cell and through the global bit line 114.

However, as noted above, the column multiplexer 111 may include some amount of leakage current, which may divert some of the target programming current from the selected bit cell. In this example, the current mirror circuit 112 may include compensating circuits, such as a replica column multiplexer and a current splitter to ensure appropriate programming current through a selected bit cell.

Control circuit 120 may also be implemented in memory circuit 100. For instance, control circuit 120 may provide various control voltages to control operation of the memory circuit 100. Examples of control voltages are described in more detail with respect to FIG. 2.

FIG. 2 is an illustration of an example program operation for memory circuit 100, according to some embodiments.

FIG. 2 shows example memory circuit 100 in more detail. For instance, bit cell array 110 is illustrated in more detail to show two columns 210, 220. FIG. 2 only shows two columns for ease of illustration, and it is understood that various embodiments may implement any appropriate quantity of columns, such as 16 or 32 etc.

Column 210 is coupled to bit line 214. Bit line 214 is coupled to a first pair of transmission gates. A first transmission gate is implemented using transistors P1 and N1, and a second transmission gate is implemented using transistors P2 and N2. Similarly, column 220 is coupled to bit line 215. Bit line 215 is coupled to a second pair of transmission gates. A first transmission gate is implemented using transistors P3 and N3, and a second transmission gate is implemented using transistors P4 and N4.

Transistors N1 and P1 form a first transmission gate. N1 has a drain (a type of current path terminal) coupled to the source (another type of current path terminal) of P1 and bit line 214. The drain of P1 and the source of N1 are coupled together. A second transmission gate includes the source of P2 and the drain of N2 coupled together at the bit line 214. In the second transmission gate, the drain of P2 is coupled to the source of N2. The drain of P2 and the source of N2 are coupled to the common bit line 114. The gates (a type of control terminal) of transistors P1 and N2 are coupled together. While the example illustrated in FIG. 2 shows source and drain terminals, it is understood that various embodiments may use symmetrical devices (or asymmetrical devices).

The body terminals of N1 and N2 are coupled to ground (a type of power supply terminal), and the body terminals of P1 and P2 are coupled to a voltage VINH.

The source of P3 is coupled to the drain of N3 and the bit line 215, and the source of N3 is coupled to the drain of P3 and to the common bit line 114. The source of P4 and the drain of N4 are coupled together and to the bit line 215. The source of N4 and the drain of P4 are coupled together. The body terminals of P3 and P4 are coupled to VINH. The body terminals of N3 and N4 are coupled to ground.

Continuing with the example, column 210 is a selected column, and column 220 is an unselected column. Therefore, the pair of transmission gates coupled to bit line 215 are configured to not pass current from column 220 to the common bit line 114. To configure the pair of transmission gates in this manner, the source of N4, the drain of P4, and the gate of N4 are coupled to VINH. Furthermore, the bit line 215 is also coupled to VINH so that the drain of N4, the source of P4, the drain of N3, and the source of P3 are also coupled to VINH. The gates of P4, N3, and P3 are all coupled to VINH as well. The gates of P4 and N3 are coupled together to 0V. In this example, the various gate voltages for the transistors of the column multiplexer 111 may be selectively provided by control circuit 120 (FIG. 1). For instance, the control circuit 120 may provide control signals that have a switchable voltage level of VINH or 0V to the gates of the transistors in column multiplexer 111.

As noted above, the pair of transmission gates coupled to column 210 and bit line 214 are configured to pass current from bit line 214 to common bit line 114. Therefore, the gate of P2 is coupled to 0V (e.g., ground) as is the gate of N1. The source of N1 and the drain of P1 are coupled to VINH, and as are the gates of P1 and N2.

Rows 221 and 222 are coupled to column 220. Only two rows are shown for ease of illustration, and it is understood that a given column may have any appropriate quantity of rows. Similarly, row 211 and row 212 are coupled to column 210. Row 221 is unselected. Therefore, in row 221, the word line (WL) voltage is 0V, and the voltages for the control gate (CG), the erase gate (EG), and the select line (SL) may be set to any appropriate level. Row 222 is coupled to unselected column 220, though it may be coupled to the same or similar voltages that are coupled to row 221. In row 222, the WL voltage is an appropriate positive voltage, and the CG voltage, the EG voltage, and the SL voltage may be set to any appropriate level.

Row 211 is an unselected row in a selected column. In row 211, the WL voltage is 0V, and the CG voltage, the EG voltage, and the SL voltage may be set at any appropriate level. Row 212 is the selected row in the selected column, and the transmission gate implemented by P2 and N2 is configured to pass current from the select line (SL) to the common bit line 114. Therefore, WL voltage is an appropriate positive voltage, and the SL, EG, and Cg voltages may be set to any appropriate level. Also, VINH is an inhibiting voltage that is used to inhibit the unselected column selected row bits from programming, and in this example it may be another appropriate positive voltage that is higher than a positive WL voltage. It should be noted that while the example of FIG. 2 is described with respect to specific voltage levels, the scope of implementations is not so limited. Rather, the scope of implementations may be adapted to use any appropriate voltage levels.

Continuing with the example, transistor 230 represents a bit cell to be programmed by current passing through transistor 230. Furthermore, the target programming current for transistor 230 may be 1.5 µA, though the scope of implementations may be adapted to use any appropriate programming current. The current through the transistor 230 is shown as I1.

Transistor 230 may be configured in this example as an NMOS device having a voltage drop represented by its gate voltage minus its source voltage. The voltage drop, thus, may correspond to the threshold voltage of transistor 230. In an example in which the threshold voltage (Vt) is an appropriate positive voltage, then the voltage on bit line 214 (Vbl) and the voltage on common bit line 114 may be the WL voltage minus Vt. The threshold voltage of a given bit cell, such as transistor 230, may be influenced by process variation for the cells in the memory array, variation in WL voltage, as well as operating temperature. While operating temperature may be somewhat controllable and WL voltage may be controllable, bit cell process variation may not be controllable, may be variable from bit to bit, and may only be known by testing.

The leakage currents through the various transmission gates in this example may be a function of VINH and Vbl. The leakage current through the transmission gate implemented by N1 and P1 is shown as I2. The leakage current through the transmission gates that are coupled to bit line 215 is shown as I3. I1 combines with I2 and with the bulk-to-drain current in P2 to sum to current I4. I4 and I3 sum to create current I5, which flows to the current mirror circuit 112.

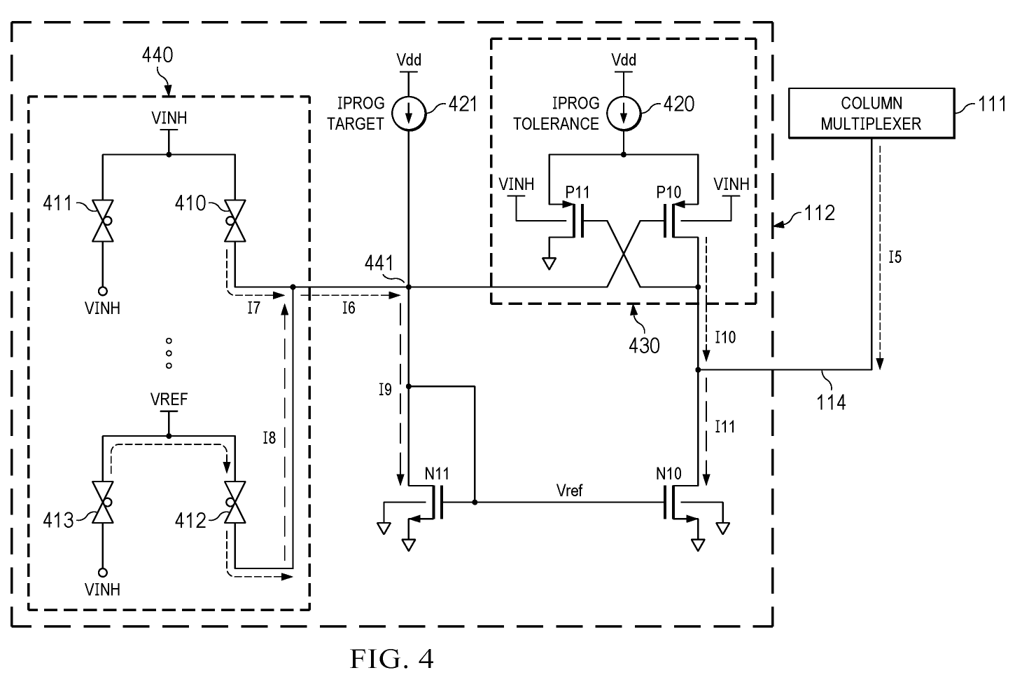

The leakage currents I2 and I3 may result in a smaller current I1 due to the operation bias conditions of current mirror circuit 112. Thus, current mirror circuit 112 includes compensating circuits to address the presence of leakage currents I2 and I3. The compensation circuits are explained in more detail with respect to FIG. 4.

The various control voltages, such as being applied as SL, EG, CG, WL, VINH, and 0V of FIG. 2 may be produced using any appropriate circuitry. For instance, in an example implementation, such control voltages may be produced by control circuit 120 (FIG. 1).

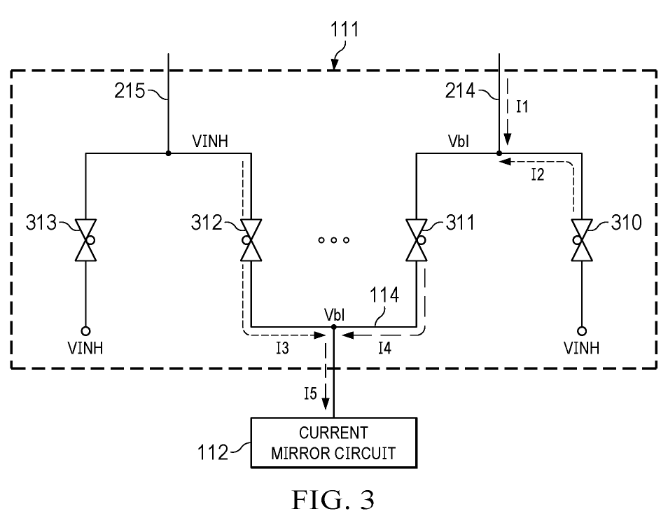

FIG. 3 is an illustration of multiplexer 111 and current mirror circuit 112, according to the example program operation described with respect to FIG. 2. FIG. 3 illustrates multiplexer 111 in a simplified form. The transmission gate that includes transistors N1 and P1 is shown as transmission gate 310. The transmission gate that includes transistors N2 and P2 is shown as transmission gate 311. The transmission gate that includes N3 and P3 is shown as transmission gate 312. The transmission gate that includes N4 and P4 is shown as transmission gate 313. The currents I1-I5 are illustrated as well. Current mirror circuit 112 receives current I5, which is a sum of currents I3-I4.

Transmission gates 310 and 311 are a first pair of transmission gates, and they are used to either pass current from bit line 214 to the common bit line 114 or to prevent current from passing from bit line 214 to the common bit line 114. Similarly, transmission gates 312 and 313 are a second pair of transmission gates, and they may be used to either pass current from bit line 215 to the common bit line 114 or to prevent current from passing from bit line 215 to the common bit line 114. In the present example, transmission gate 312 is off, and transmission gate 313 is on to pass VINH to the unselected bit line 215. Similarly, transmission gate 310 is also off, and transmission gate 311 is on.

Once again, the quantity of transmission gates in multiplexer 111 is shown as four total transmission gates for ease of illustration, where those four total transmission gates perform a multiplexing function with respect to two bit lines 214, 215. However, the scope of implementations may be adapted to include a larger quantity of transmission gates and a larger quantity of columns to be multiplexed by those transmission gates. For instance, in an example in which there are 16 columns total, one of which is selected, there may be 32 total transmission gates. In an example with 16 columns, transmission gates 312 and 313 (which are off but still have leakage) may be replicated 14 times for a total of 30 transmission gates to multiplex 15 unselected columns. Thus, if current I3 represents leakage current from 15 total transmission gate pairs, current I3 may be relatively large and may be more than an order of magnitude larger than current I2.

FIG. 4 is an illustration of the example column multiplexer 111 and the current mirror circuit 112, according to the example program operation described with respect to FIGS. 2-3.

Current mirror circuit 112 includes a current mirror having two legs. A first leg includes current source 421 and diode-connected transistor N11. A second leg includes transistor N10. Transistor N11 has a drain coupled to current source 421 and a source coupled to a power supply terminal (ground). The drain of transistor N11 is coupled to the gate of transistor N11. Transistor N10 has a drain that is coupled to current splitter circuit 430 and to the common bit line 114. The source of N10 is coupled to ground, and the gate of N10 is coupled to the gate of N11. The body terminals of N10 and N11 are both coupled to ground as well.

Current I9 is a sum of current I6, current I8, and IPROG Target. Current I11 is a sum of current I5 and I10. The structure of current mirror circuit 112 causes current I9 to be replicated at current I11. In this example, the current mirror has a gain of one, so that current I11 has a same value as current I9, though the scope of embodiments may include a current mirror having any appropriate gain.

Current mirror circuit 112 includes a replica column multiplexer 440, illustrated by pairs of transmission gates. A first pair of transmission gates includes transmission gates 410 and 411, and a second pair of transmission gates includes transmission gates 412 and 413. FIG. 4 illustrates two pairs of transmission gates, which correspond to the two pairs of transmission gates shown in FIGS. 2-3. However, it is understood that the replica column multiplexer 440 of current mirror circuit 112 may have a same quantity (an integer M) of pairs of transmission gates as the quantity (e.g., an integer N) of transmission gates of the column multiplexer 111. Thus, if the column multiplexer 111 includes 16 total pairs of transmission gates, then the replica column multiplexer 440 may include 16 total pairs of transmission gates as well. Of course, the scope of implementations may be scaled as appropriate for a given application. For example, the replica column multiplexer 440 may have half as many pairs of transmission gates as column multiplexer 111 if the current mirror circuit 112 is structured to have a 2:1 gain and the programming target current supplied by current source 421 is scaled appropriately.

Replica column multiplexer 440 may be implemented using transistors that are a same size and produced by a same process as the transistors of the pairs of transmission gates in column multiplexer 111. For instance, transmission gate 411 may have transistors that are a same size and built using a same process as transistors N4 and P4, and transmission gate 410 may have transistors that are a same size and built using a same process as transistors N3 and P3 (FIG. 2). Thus, transmission gates 410 and 411 may be replicas of transmission gates 312 and 313, having similar process variation and be expected to operate in a same or similar manner over voltage and temperature variations. Similarly, transmission gates 412, 413 may be replicas of transmission gates 310 and 311, having similar process variation and expected to operate in a same or similar manner over voltage and temperature variations. As implemented in an IC, such as chip 101, the transistors of replica column multiplexer 440 may be implemented in relative proximity to the transistors of column multiplexer 111.

Further in this example, each of the pairs of transmission gates in replica column multiplexer 440 may be arranged the same as and have the same voltage controls as the transmission gates of column multiplexer 111. For instance, the various control voltages, such as VINH and 0V may be applied to the replica transmission gates of replica column multiplexer 440 in a same or similar manner as such control voltages are applied to the transmission gates of column multiplexer 111. Also, replica transmission gates 410, 411 may be replicas of transmission gates 312, 313, which are unselected in the examples of FIGS. 2-3. Similarly, transmission gates 412, 413 are replicas of transmission gates 310, 311, which correspond to a selected bit line. Thus, transmission gate 313 has both of its terminals coupled to VINH, and transmission gate 312 has one terminal coupled to VINH and one terminal coupled to the common bit line 114. Similarly, transmission gate 411 is coupled at both of its terminals to VINH, and transmission gate 410 has one terminal coupled to VINH and the other terminal coupled to node 441. This causes transmission gates 410, 411 to approximate the leakage current of transmission gates 312, 313.

Transmission gate 413 is disabled, and transmission gate 412 is enabled. Since transmission gate 412 is enabled and is coupled to node 441, that causes the VREF voltage to be at the node between transmission gate 413 and transmission gate 412. Transmission gate 413 has VINH on one terminal and VREF on the other terminal. Such an arrangement may cause transmission gates 412, 413 to approximate the leakage of transmission gates 310, 311. In replica column multiplexers 440 with more than two pairs of transmission gates, the additional pairs of transmission gates may be coupled to VINH (as opposed to VREF) similar to transmission gates 410, 411 to approximate the leakage current of other unselected paths of the column multiplexer 111.

Each of the pairs of transmission gates of replica column multiplexer 440 are coupled to node 441, just as each of the pairs of transmission gates of column multiplexer 111 are coupled to common bit line 114. The pair of transmission gates including 410, 411 has leakage current shown as I7, and the pair of transmission gates including 412, 413 is shown as current I8.

One difference between the replica column multiplexer 440 and the column multiplexer 111 is that the transmission gates of the replica column multiplexer 440 are not coupled to columns of the bit cell array 110. Other than that difference, the structure of replica column multiplexer 440 is the same as the structure of column multiplexer 111.

As a result, the cumulative leakage (I6) from the pairs of transmission gates of the replica column multiplexer 440 is expected to be proportional but not the same as the cumulative leakage from the pairs of transmission gates of the column multiplexer 111 (e.g., current I2+ current I3). Error between the two cumulative current may be due to VREFVREF of the diode not matching the Vbl-Vt drop of the selected bit cell. The splitter circuit 430 (discussed below) is designed to correct for this error.

Current generator 421 produces current IPROG Target, which may be set to be a target programming current for a bit cell (e.g., transistor 230 of FIG. 2). In one example, IPROG Target may be 1.7 µA, though the scope of implementations may use any appropriate target programming current. In an example in which current I6 and the sum of current I2 and I3 (FIG. 3) are both 1 µA and IPROG Target is 1.7 µA, then current I5 and I9 would both be expected to be 2.7 µA. In such an example, it would be expected that the current through the bit cell (I1) would be 1.7 µA, thereby avoiding under-programming or over-programming. Of course, this example discounts the effect of splitter circuit 430, which is discussed in more detail below.

In one example implementation, transistor N11 may be sized so that its gate-drain voltage (VREF) is approximately equal to a nominal value of the bit line voltage Vbl, which appears on bit line 214 and common bit line 114. As noted above, the bit line voltage Vbl may be a function of the voltage drop across a bit cell, such as transistor 230 (FIG. 2). The voltage drop across a bit cell may vary from bit cell to bit cell and may be somewhat unpredictable. Thus, some design operations may include using experimentation and/or simulation to set VREF equal to a mean or median Vbl. For instance, for example bit cell array 110, Vbl for a multitude of different bits may range from Va (a lower positive value) to Vb (a higher positive value), with a mean (Vmean) at approximately (Va-Vb)/2. The design operation may include sizing transistor N11 so that VREF is approximately equal to Vmean. Transistor N10 may be designed to cause a mirroring ratio of one. Designing transistor N11 so that VREF is approximately equal to a mean or median Vbl may help to ensure that current I6 is approximately equal to the sum of currents I2 and I3 for whichever bit is being programmed.

The process for a bit, such as for transistor 230, may be a different process from a CMOS process used to implement the various transistors that are used for transmission gates and for the current mirror circuit 112. Furthermore, bit process variation may be higher than a CMOS process in some examples. Therefore, there may be process corners for some bits and temperature corners that may cause aberrant operation. For instance, a bit may be an outlier, which may be expected to result in high Vbl that would otherwise cause over-programming of the bit or a low Vbl that would otherwise cause under-programming of the bit. Splitter circuit 430 is a compensating circuit that is designed to address outlying process bit variation to avoid over-programming.

Splitter circuit 430 includes current source 420, which generates a current IPROG Tolerance. Transistor P10 is implemented as a PMOS transistor having its source coupled to the source of PMOS transistor P11 and to the output of current source 420. The drain of P10 is coupled to the gate of P11, to the common bit line 114, and to the drain of transistor N10. The gate of P10 is coupled to node 441, so it is also coupled to current source 421, replica column multiplexer 440, and to the drain of N11. The body terminal of P10 is coupled to VINH. Transistor P11 has its source coupled to the source of P10 and to the output of current source 420. The drain of P11 is coupled to ground. The gate of P11 is coupled to the drain of P10, the drain of N10, and to the common bit line 114. The body terminal of P11 is coupled to VINH. Thus, the gate of P11 is coupled to the second current mirror leg, and the gate of P10 is coupled to the first current mirror leg.

The value of IPROG Tolerance may be set in any appropriate manner. For instance, using experimentation and/or simulation, a designer may determine that bit process variation may result in a highest bit programming current (current I1) of a certain value. In an example in which IPROG Target is 1.7 µA, a highest bit programming current may be as high as 3.7 µA (without intervention of the splitter circuit 430). Furthermore, a designer may know beforehand that a range of appropriate programming voltages may be 0.7 µA-2.7 µA. The designer may then subtract the highest appropriate programming voltage (e.g., 2.7 µA) from the highest possible programming voltage (e.g., 3.7 µA) and then use that difference (e.g., 1.0 µA) as IPROG Tolerance to prevent a high-current scenario.

The splitter circuit 430 is configured to operate based on a voltage difference between VREF on the first current mirror leg and Vbl on common bit line 114 and on the second current mirror leg. In an example in which VREF is higher than Vbl, then transistor P10 is either weakly on or is off and transistor P11 is on or is more on than transistor P10. In other words, when VREF is higher than Vbl, then splitter circuit 430 diverts IPROG Tolerance to ground to avoid reducing the programming current.

In an example in which VREF is lower than Vbl, transistor P11 is either off or is weakly on and transistor P10 is on or more on than transistor P11. In this scenario, the splitter circuit 430 diverts all or most of the current IPROG Tolerance to the second leg of the current mirror as current I10. As current I10 increases, that reduces a programming current (current I1) through the bit. Reducing the programming current may reduce or eliminate over-programming of a bit, thereby extending a life of the bit cell array 110.

The current IPROG Tolerance may be acquired from any appropriate circuitry within circuit 100. In one example, current source 420 may be associated with a reading path (not shown) of circuit 100, which may be potentially advantageous because reading current would not be expected to be used during a program operation.

In some implementations, the column multiplexer 111 may be implemented using an architecture other than pairs of transmission gates. The scope of implementations may be adapted for any column multiplexer architecture. In an example in which the column multiplexer 111 is implemented using a different architecture, the circuits of that different architecture may be replicated to create replica column multiplexer 440.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A circuit comprising:
a first column multiplexer;
a common bitline coupled to the first column multiplexer;
a current mirror circuit coupled to the common bitline, wherein the current mirror circuit has:
a first leg having:
a current source; and
a diode coupled between the current source and a power supply terminal;
a second leg having a first transistor that has a control terminal coupled to a terminal of the diode, wherein a current path terminal of the first transistor is coupled to the first column multiplexer; and
a second column multiplexer coupled to the diode.

2. The circuit of claim 1, wherein the first column multiplexer includes N pairs of transmission gates, each pair of transmission gates being coupled to a column, further wherein the second column multiplexer includes N pairs of transmission gates, wherein N is an integer greater than one.

3. The circuit of claim 2, wherein the pairs of transmission gates of the first column multiplexer are coupled to the first transistor via the common bitline, further wherein the pairs of transmission gates of the second column multiplexer are coupled to the diode.

4. The circuit of claim 2, wherein each transmission gate of the pairs of transmission gates of the first column multiplexer includes a P type metal oxide semiconductor (PMOS) transistor coupled to a N type metal oxide semiconductor (NMOS) transistor, wherein the PMOS transistor has a body terminal configured to be coupled to a first voltage.

5. The circuit of claim 4, wherein each transmission gate of the pairs of transmission gates of the second column multiplexer includes a PMOS transistor and an NMOS transistor.

6. The circuit of claim 1, wherein the first column multiplexer includes N pairs of transmission gates, each pair of transmission gates having a first transmission gate and a second transmission gate, wherein each first transmission gate of the first column multiplexer is coupled to the common bitline, and wherein each second transmission gate of the first column multiplexer is configured to be coupled to receive a first voltage, and wherein N is an integer greater than one.

7. The circuit of claim 6, wherein the second column multiplexer includes M pairs of transmission gates, each pair of transmission gates of the second column multiplexer having a first transmission gate and a second transmission gate, wherein each first transmission gate of the second column multiplexer is coupled to the diode and to the first voltage, and wherein each second transmission gate is configured to be coupled to receive the first voltage.

8. The circuit of claim 7, wherein the first column multiplexer has a multiplexing ratio of N:1.

9. The circuit of claim 7, wherein N and M are equal.

10. A circuit comprising:
a column multiplexer;
a common bitline coupled to the column multiplexer;
a current mirror circuit coupled to the common bitline, wherein the current mirror circuit has:
a first leg having:
a first current source; and
a diode coupled between the first current source and a power supply terminal; and
a second leg having a first transistor that has a control terminal coupled to a terminal of the diode, wherein a current path terminal of the first transistor is coupled to the column multiplexer; and
a second current source;
a second transistor having first and second current path terminals and a control terminal; and
a third transistor having first and second current path terminals and a control terminal, wherein the first current path terminal of the second transistor is coupled to the second current source, the second current path terminal of the second transistor is coupled to the power supply terminal, and the control terminal of the second transistor is coupled to the second current path terminal of the third transistor, further wherein the first current path terminal of the third transistor is coupled to the second current source and the control terminal of the third transistor is coupled to the diode.

11. The circuit of claim 10, wherein the first transistor has first and second current path terminals, wherein the first current path terminal of the first transistor is coupled to the column multiplexer, and wherein the second current path terminal of the first transistor is coupled to the power supply terminal.

12. The circuit of claim 10, wherein the diode includes a fourth transistor having first and second current path terminals, further wherein the first current path terminal of the fourth transistor is coupled to the first current source and to the control terminal of the fourth transistor and to the control terminal of the first transistor.

13. The circuit of claim 12, further comprising:
a replica current mirror circuit coupled to the first current path terminal of the fourth transistor.

14. A circuit comprising:
an array of bit cells, the array of bit cells having a plurality of columns;
a column multiplexer, wherein each of the columns is coupled to the column multiplexer, wherein the column multiplexer has N pairs of transmission gates, each pair of transmission gates being coupled to a respective column and to a common bitline, wherein N is an integer greater than one;
a current mirror circuit having a first leg and a second leg, wherein the second leg of the current mirror circuit is coupled to the common bitline;
M pairs of transmission gates coupled to the first leg of the current mirror circuit, wherein M is an integer greater than one;
a first transistor having first and second current path terminals and a control terminal; and
a second transistor having first and second current path terminals and a control terminal, wherein the first current path terminal of the first transistor and the first current path terminal of the second transistor are coupled to a first current source, wherein the second current path terminal of the first transistor is coupled to a power supply terminal, wherein the second current path terminal of the second transistor is coupled to the common bitline, and wherein the control terminal of the second transistor is coupled to the first leg of the current mirror circuit.

15. The circuit of claim 14, wherein N and M are equal.

16. The circuit of claim 14, wherein a first column of the plurality of columns includes a first bit cell of the array of bit cells, wherein the first column is coupled to a first pair of transmission gates of the N pairs of transmission gates, further wherein the first pair of transmission gates is configured to create a current path traversing a select line, the first bit cell, the common bit line, and the second leg of the current mirror circuit.

17. The circuit of claim 16, wherein the first leg of the current mirror circuit includes a third transistor having first and second current path terminals and a control terminal, wherein the first current path terminal of the third transistor is coupled to the control terminal of the third transistor and to a control terminal of a fourth transistor, wherein the fourth transistor is arranged in the second leg of the current mirror circuit.

18. The circuit of claim 17, wherein the fourth transistor has first and second current path terminals, wherein the first current path terminal of the fourth transistor is coupled to the second current path terminal of the second transistor, and wherein the second current path terminal of the fourth transistor is coupled to a power supply terminal.

19. The circuit of claim 17, wherein the M pairs of transmission gates are coupled to the first current path terminal of the third transistor.

20. The circuit of claim 14, wherein the column multiplexer has a multiplexing ratio of N.
